(19) United States
(12) Patent Application Publication
(10) Pub. No.: US 2013/0068520 A1
(43) Pub. Date: Mar. 21, 2013

(54) ELECTROMAGNETIC SHIELDING DEVICE AND ELECTRONIC APPARATUS

(71) Applicant: JUN-WEI WANG, Shenzhen City (CN)

(72) Inventor: JUN-WEI WANG, Shenzhen City (CN)

(73) Assignees: HON HAI PRECISION INDUSTRY CO., LTD., Tu-Cheng (TW); HONG FU JIN PRECISION INDUSTRY (ShenZhen) CO., LTD., Shenzhen City (CN)

(21) Appl. No.: 13/455,248

(22) Filed: Apr. 25, 2012

(30) Foreign Application Priority Data
Sep. 21, 2011 (CN) 201110281735.2

(51) Int. Cl. H05K 9/00

(52) U.S. Cl. 174/377

(57) ABSTRACT

An electromagnetic shielding device for shielding electromagnetic energy generated by an electronic apparatus. The electromagnetic shielding device includes a base board and a number of protrusions formed on the base board. The length of each protrusion along a direction perpendicular to the base board is adjustable. The amount of electromagnetic energy can be absorbed by the electromagnetic shielding device is adjusted according to the length of the protrusion.

### 1. TECHNICAL FIELD

The disclosure generally relates to electromagnetic shielding, and particularly, to an electromagnetic shielding device and an electronic apparatus using the electromagnetic shielding device.

### 2. DESCRIPTION OF RELATED ART

An electromagnetic shielding device shielding an electronic apparatus absorbs the electronmagnetic energy generated by the electronic apparatus. The shape, among other features, of the electromagnetic shielding device determines the amount of electromagnetic energy that can be absorbed by the electromagnetic shielding device. The electromagnetic energy generated by different electronic apparatus is not the same. Even the same electronic apparatus will generate variable electromagnetic energy if the electronic apparatus works under different working conditions. However, the shape of electromagnetic shielding devices set on an electronic apparatus are usually unchangeable. Thus, the electronmagnetic shielding device with a fixed shape may not be used by different electronic apparatus having different shapes.

Therefore, it is desirable to provide an electromagnetic shielding device and an electronic apparatus which can overcome the above-mentioned problems.

### BRIEF DESCRIPTION OF THE DRAWINGS

Many aspects of the disclosure can be better understood with reference to the following drawings. The components in the drawings are not necessarily drawn to scale, the emphasis instead being placed upon clearly illustrating the principles of the disclosure. Moreover, in the drawings, like reference numerals designate corresponding parts throughout the several views.

FIG. 1 is an isometric view of an electronic apparatus in accordance with a first embodiment of present disclosure, the electronic apparatus including a electromagnetic shielding device.

FIG. 2 is an isometric view of the electromagnetic shielding device of FIG. 1.

FIG. 3 is a cross-sectional view of the electromagnetic shielding device taken along line III-III.

FIG. 4 is a cross-sectional view of the electromagnetic shielding device in accordance with a second embodiment of present disclosure.

FIG. 5 is a an isometric view of an electronic apparatus in accordance with a third embodiment of present disclosure.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean at least one.

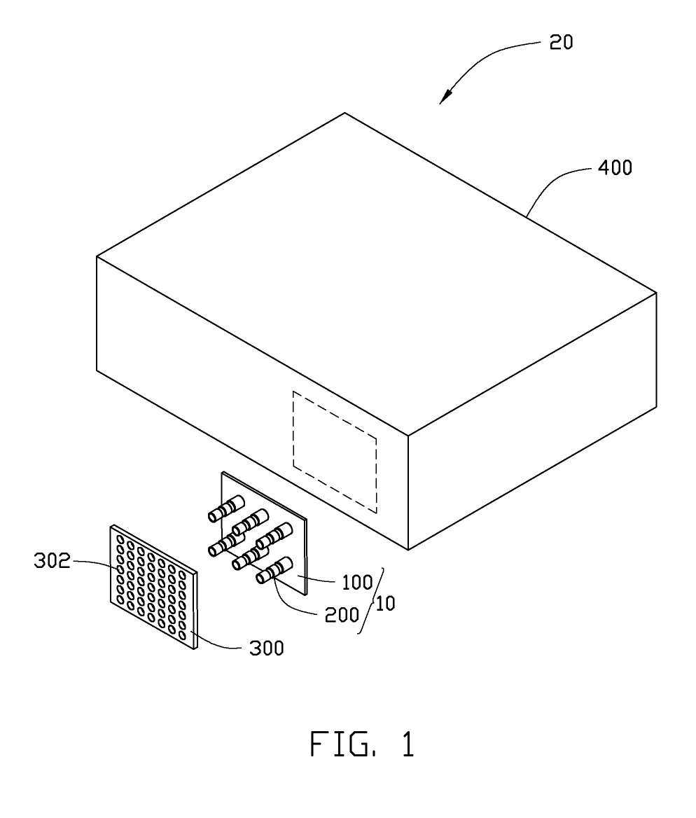

FIG. 1, is an electronic apparatus 20, according to a first embodiment, including an enclosure 400, an eletronmagnetic shielding device 10, and an adjusting sheet 300. The electronmagnetic shielding device 10 is fastened on the enclosure 400 to absorb electronmagnetic energy generated by the electronic apparatus 20. The adjusting sheet 300 further absorbs electronmagnetic energy generated by the electronic apparatus 20. In one embodiment, the adjusting sheet 300 also adjusts the shape of the electronmagentic shielding device 10.

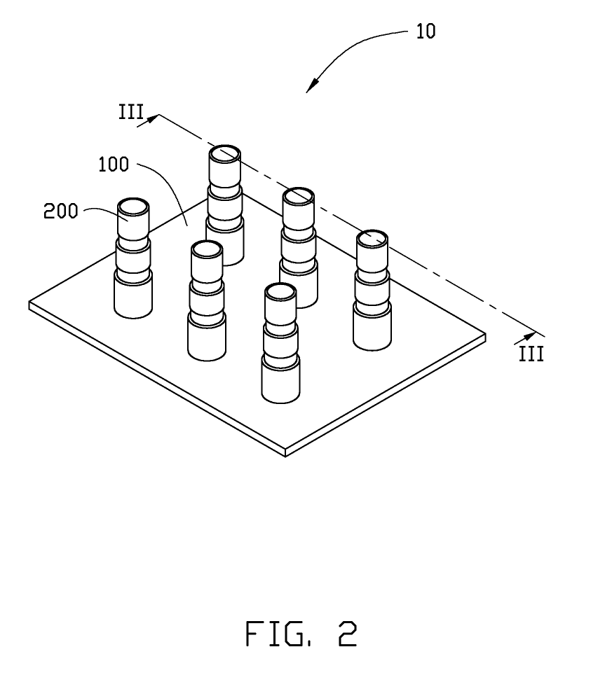

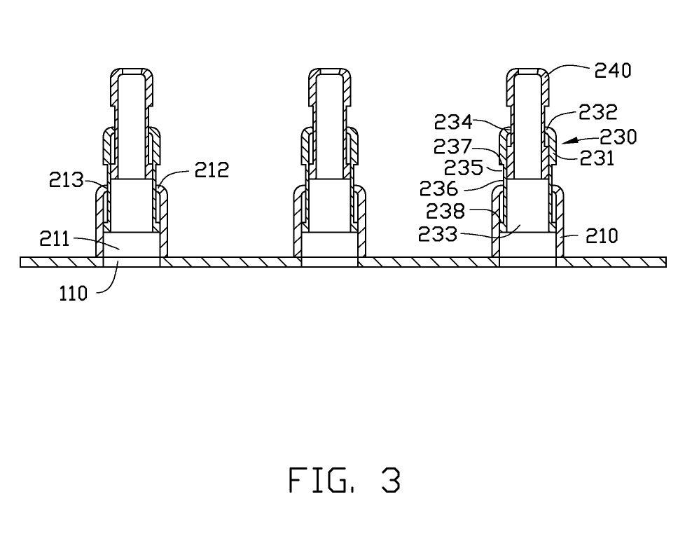

FIGS. 2 and 3, show the electromagenic shielding device 10 including a base board 100 and a number of protrusions 200. The base board 100 defines a number of first through holes 110. The base board 100 is fastened on the enclosure 400. The first through holes 110 can be used for dissipating heat generated by the electronic apparatus 10. The material of the base board 100 is selected from the group consisting of metal and plastic. In this embodiment, the base board 100 is made of metal.

The protrusions 200 are hollow and columnar shaped and absorb electronmagnetic energy. The longer the protrusion 200 is, more electronmagnetic energy can be absorbed by the protrusions 200. In one embodiment, each of the protrusions 200 includes a primary sleeve 210 and at least one secondary sleeve 230. The primary sleeve 210 is a cylindrical hollow pillar. The primary sleeve 210 defines a bottom opening 211 at a distal end of the primary sleeve 210 and includes a top plate 212 opposite to the bottom opening 211. The diameter of the bottom opening 211 is equal to the diameter of the first through hole 110. The primary sleeve 210 defines a top opening 213 at a center of the top plate 212. The diameter of the top opening 213 is smaller than the diameter of the bottom opening 211. The primary sleeve 210 is fastened on the base board 100 at the position where the first through hole 110 is defined. The periphery of the bottom opening 211 aligns with the periphery of the corresponding first through hole 110. The first through hole 110 is in communication with the interior part of the primary sleeve 210.

The secondary sleeve 230 is a cylindrical hollow pillar and includes a sidewall 231 and an upper plate 232 perpendicularly connected to a distal end of the sidewall 231. The secondary sleeve 230 defines a lower opening 233 at the other distal end opposite to the upper plate 232. The secondary sleeve 230 defines an upper opening 234 at a center of the upper plate 232. The diameter of the upper opening 234 is smaller than the diameter of the lower opening 233.

The secondary sleeve 230 defines a sliding groove 235 on the sidewall around a symmetric axis of the secondary sleeve. The sliding groove 235 is defined at a middle part of the sidewall 231. The length of sliding groove 235 along the longitudinal direction of the secondary sleeve 230 is one third of the total length of the sidewall 231 along the longitudinal direction of the secondary sleeve 230.

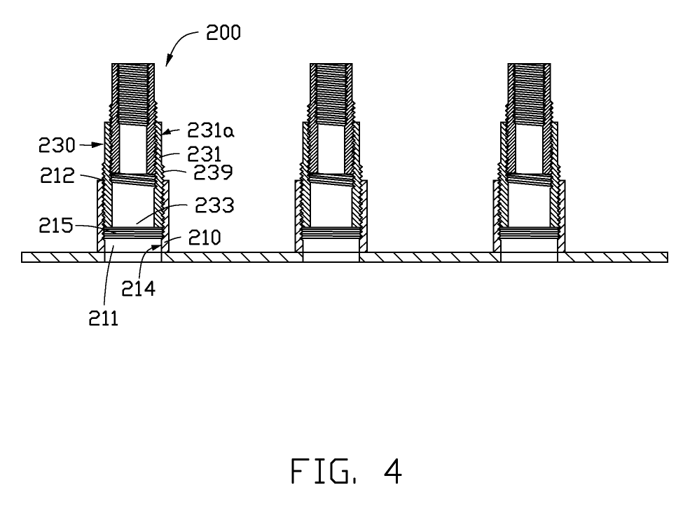

The sliding groove 235 defines a side surface 236 parallel to an outer surface 231a (FIG. 4) of the sidewall 231, an upper surface 237 perpendicularly connected to the side surface 236, and a lower surface 238 perpendicularly connected to the side surface 236 and opposite to the upper surface 237. The upper surface 237 is near the upper plate 232. The lower surface 238 is near the lower opening 233. The outer diameter of the sidewall 231 out of the sliding groove 235 is slightly smaller than the inner diameter of the primary sleeve 210 and larger than the diameter of the top opening 212. The outer diameter of the sidewall 231 inside the sliding groove 235 is slightly smaller than the diameter of the top opening 212.

A lower part of the secondary sleeve 230 between the lower opening 233 and the sliding groove 235 is tightly received in the primary sleeve 210. An upper part of the secondary sleeve 230 between the upper plate 232 and the sliding groove 235 extends out of the primary sleeve 210 from the top opening 213. The periphery of the top opening 213 tightly engages with the side surface 236. Thus, the secondary sleeve 230 is limited to slide between the upper surface 237 and the lower surface 238 along the longitudinal direction of the primary sleeve 210 for adjusting the total length of the protrusion 200. The electronmagnetic energy absorbed by the protrusions 200 is adjusted according to the length of the protrusion 200.

In order to increase the protrusion 200 to maximum length, the protrusion 200 may include more than one secondary sleeve 230, for example, a first secondary sleeve 230, a second secondary sleeve 240, . . . , nth secondary sleeve. The second secondary sleeve 240 is similarly with the first secondary sleeve 230 in shape but smaller in radial dimension. Thus, the second secondary sleeve 240 can be tightly received in the first secondary sleeve 230 via the sliding engagement as that between the first secondary sleeve 230 and the primary sleeve 210. Similarly, the third secondary sleeve (not shown) is tightly received in the second secondary sleeve 240, the fourth secondary sleeve (not shown) is tightly received in the third secondary sleeve, . . . , and the nth secondary sleeve is tightly received in the (n−1)th secondary sleeve. In this embodiment, each of the protrusions includes a first secondary sleeve 230 and a second secondary sleeve 240.

FIG. 4, shows a second embodiment, the primary sleeve 210 including an inner surface 214 and defines an internal screw thread 215 on the inner surface 214. The diameter of the top opening 212 is equal to the diameter of the bottom opening 211. The secondary sleeve 230 defines an outer screw thread 239 on a part of the outer surface 231a near the lower opening 233. The outer diameter of the secondary sleeve 230 is slightly smaller than the inner diameter of the primary sleeve 210. A bottom part of the secondary sleeve 230 is retractablely received in the primary sleeve 210 by engaging the outer screw thread 239 with the inner screw thread 215. Similarly, if the number of secondary sleeves 230 is more than one, the rest of the secondary sleeves 230 are connected one by one via the threaded engagement the same as between the primary sleeve 210 and the first secondary sleeve 230. Therefore, the total length of the protrusion 200 can be adjusted by screwing at least one of the secondary sleeves 230 in or out of the adjacent secondary sleeves 230.

The primary sleeve 210 and the secondary sleeve 230 are selected from a group consisting of rectangular wave guide tubes, circular wave guide tubes, and elliptic wave guide tubes, for example. The material of the primary sleeve 210 and the secondary sleeve 230 are selected from the group consisting of copper, aluminium, sliver, and gold, for example.

The adjusting sheet 300 is a planar metal sheet and defines a number of second through holes 302 corresponding to the protrusions 200. The diameter of the second through hole 302 is slightly smaller than the diameter of the upper plate 232 of the secondary sleeve 230 farthest away from the base board 100. The adjusting sheet 300 engages with the protrusions 200 by the second through holes 302 correspondingly sleeved on the secondary sleeve 230 farthest away from the base board 100. Thus, the extending length of more than one protrusions 200 can be adjusted together at a same time.

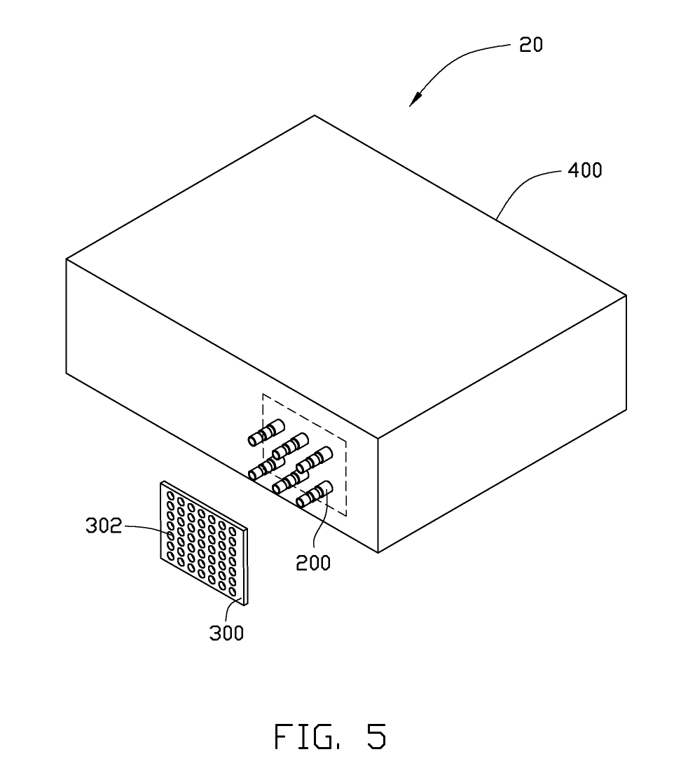

FIG. 5, shows in a third embodiment, the base board 100 can be omitted. The first through holes 110 are directly defined on the enclosure 400. The protrusions 200 are directly fastened on the enclosure 400 at the position where the first through hole 110 is defined.

It is believed that the present embodiments and their advantages will be understood from the foregoing description, and it will be apparent that various changes may be made thereto without departing from the spirit and scope of the disclosure or sacrificing all of its material advantages, the examples hereinbefore described merely being preferred or exemplary embodiments of the disclosure.

What is claimed is:

1. An electromagnetic shielding device comprising:
a base board; and
a plurality of hollow protrusions formed on the base board, the length of each protrusion along a direction perpendicular to the base board is adjustable.

2. The electromagnetic shielding device of claim 1, wherein each protrusion comprises a primary sleeve and more than one secondary sleeves, one of the secondary sleeve tightly retractablely received in the primary sleeve, the other secondary sleeves tightly retractablely connected one by one.

3. The electromagnetic shielding device of claim 2, wherein the primary sleeve defines a bottom opening at a distal end of the primary sleeve and comprises a top plate opposite to the bottom opening, the primary sleeve defines a top opening on the top plate.

4. The electromagnetic shielding device of claim 3, wherein the secondary sleeve comprises a sidewall and an upper plate perpendicularly connected to a distal end of the sidewall, the secondary sleeve defines an upper opening on the upper plate, a lower opening at the other distal end opposite to the upper plate, and a sliding groove on the sidewall around a symmetric axis of the secondary sleeve, the outer diameter of the sidewall out of the sliding groove is slightly smaller than the inner diameter of the primary sleeve and larger than the diameter of the top opening, the outer diameter of the sidewall inside the sliding groove is slightly smaller than diameter of the top opening, a lower part of the secondary sleeve between the lower opening and the sliding groove is tightly received in the primary sleeve, an upper part of the secondary sleeve between the upper plate and the sliding groove extends out of the primary sleeve from the top opening.

5. The electromagnetic shielding device of claim 4, wherein the sliding groove defines a side surface parallel to the sidewall, an upper end surface perpendicularly connected to the side surface, and a lower end surface perpendicularly connected to the side surface and opposite to the upper end surface, the periphery of the top opening tightly engages with the side surface, the secondary sleeve is limited to slide between the upper surface and the lower surface along the longitudinal direction of the primary sleeve.

6. The electromagnetic shielding device of claim 5, wherein the length of the sliding groove along the longitudinal direction of the secondary sleeve is one third of the total length of the sidewall along the longitudinal direction of the secondary sleeve.

7. The electromagnetic shielding device of claim 6, wherein the connection between two of the other secondary sleeves is the same as the connection between the primary sleeve and the secondary sleeve.

8. The electromagnetic shielding device of claim 2, wherein the primary sleeve comprises an inner surface and defines an inner screw thread on the inner surface, and a top opening at one distal end of the primary sleeve, the structure of the secondary sleeve is substantially similar to the primary sleeve in shape except that the secondary sleeve further defines an outer screw thread on a part of the outer surface near a bottom end of the secondary sleeve, the outer diameter of the secondary sleeve is slightly small than the inner diameter of the primary sleeve, a bottom part of the secondary sleeve is retractablely received in the primary sleeve via the top opening by engaging the outer screw thread with the inner screw thread.

9. The electromagnetic shielding device of claim 8, wherein the connection between two of the other secondary sleeves is the same as the connection between the primary sleeve and the secondary sleeve.

10. The electromagnetic shielding device of claim 3, wherein the base board defines a plurality of first through holes, the diameter of the first through hole is equal to the diameter of the bottom opening, the primary sleeve is fastened on the base board at the position where the first through hole is defined, the periphery of the bottom opening aligns with the periphery of the corresponding first through hole, the first through hole in communication with the interior part of the primary sleeve.

11. A electronic apparatus comprising:
an enclosure; and
an electromagnetic shielding device fastened on the enclosure, the electromagnetic shielding device comprises a plurality of hollow protrusions, the longitudinal length of each protrusion is adjustable.

12. The electronic apparatus of claim 11, wherein each protrusion comprises a primary sleeve and more than one secondary sleeves, one of the secondary sleeve tightly slidably received in the primary sleeve, the other secondary sleeves tightly slidably connected one by one.

13. The electronic apparatus of claim 12, wherein the primary sleeve defines a bottom opening at a distal end of the primary sleeve and comprises a top plate opposite to the bottom opening, the primary sleeve defines a top opening on the top plate.

14. The electronic apparatus of claim 13, wherein the secondary sleeve comprises a sidewall and an upper plate perpendicularly connected to a distal end of the sidewall, the secondary sleeve defines an upper opening on the upper plate, a lower opening at the other distal end opposite to the upper plate, and a sliding groove on the sidewall around a symmetric axis of the secondary sleeve, the outer diameter of the sidewall out of the sliding groove is slightly smaller than the inner diameter of the primary sleeve and larger than the diameter of the top opening, the outer diameter of the sidewall inside the sliding groove is slightly smaller than diameter of the top opening, a lower part of the secondary sleeve between the lower opening and the sliding groove is tightly received in the primary sleeve, an upper part of the secondary sleeve between the upper plate and the sliding groove extends out of the primary sleeve from the top opening.

15. The electronic apparatus of claim 14, wherein the sliding groove defines a side surface parallel to the sidewall, an upper end surface perpendicularly connected to the side surface, and a lower end surface perpendicularly connected to the side surface and opposite to the upper end surface, the periphery of the top opening tightly engages with the side surface, the secondary sleeve is limited to slides between the upper surface and the lower surface along the longitudinal direction of the primary sleeve.

16. The electronic apparatus of claim 15, the length of sliding groove along the longitudinal direction of the secondary sleeve is one third of the total length of the sidewall along the longitudinal direction of the secondary sleeve.

17. The electronic apparatus of claim 16, wherein the connection between two of the other secondary sleeves is the same as the connection between the primary sleeve and one of the secondary sleeves.

18. The electronic apparatus of claim 13, wherein the base board defines a plurality of first through holes, the diameter of the first through hole is equal to the diameter of the bottom opening, the primary sleeve is fastened on the base board at the position where the first through hole is defined, the periphery of the bottom opening aligns with the periphery of the corresponding first through hole, the first through hole in communication with the interior part of the primary sleeve.

19. The electronic apparatus of claim 13, wherein the electromagnetic shielding device further comprises a base board, the base board defines a plurality of first through holes, the diameter of the first through hole is equal to the diameter of the bottom opening, the primary sleeve is fastened on the base board at the position where the first through hole is defined, the periphery of the bottom opening aligns with the periphery of the corresponding first through hole, the first through hole in communication with the interior part of the primary sleeve.

20. The electronic apparatus of claim 13, wherein the enclosure defines a plurality of first through holes, the protrusions are directly fastened on the enclosure at the position where the first through hole is defined, the diameter of the first through hole is equal to the diameter of the bottom opening, the periphery of the bottom opening aligns with the periphery of the corresponding first through hole, the first through hole in communication with the interior part of the primary sleeve.
